(19) United States
(12) Patent Application Publication
(10) Pub. No.: US 2012/0241717 A1
(43) Pub. Date: Sep. 27, 2012

(54) Organic Photosensitive Optoelectronic Devices

(75) Inventors: Timothy Jones, Coventry (GB); Ross Hatton, Coventry (GB)

(73) Assignee: UNIVERSITY OF WARWICK, Coventry (GB)

(21) Appl. No.: 13/393,759

(22) PCT Filed: Sep. 3, 2010
(86) PCT No.: PCT/GB2010/001673

§ 371 Date: May 31, 2012

(30) Foreign Application Priority Data
Sep. 4, 2009 (GB) 0915501.1

(51) Int. Cl. H01L 31/0256; B82Y 99/00

(52) U.S. Cl. 257/12; 257/53; 977/734; 977/742; 257/E31.003

(57) ABSTRACT

A photosensitive optoelectronic device (1) comprises a plurality of organic semiconductor sub-cells (10, 11, 12, 13) arranged in a stack between electrodes (3, 5), each sub-cell comprising donor material (14, 16, 23, 25) and acceptor material (15, 17, 24, 26) providing a heterojunction. There is a recombination layer (19, 22, 28) between adjacent sub-cells. The sub-cells are arranged in two groups (20, 29). The sub-cells (10, 11; 12, 13) within a group (20; 29) are responsive over substantially the same part of the light spectrum. The groups (20, 29) differ substantially from each other in respect of the parts of the light spectrum over which their respective sub-cells are responsive.

This invention relates to organic photosensitive optoelectronic devices, incorporating an organic semiconductor cell comprising donor material and acceptor material. Such devices can be used, for example, to generate electricity from solar radiation.

The invention is more particularly concerned with such devices in which a cell incorporates a heterojunction between donor and acceptor materials. Charge separation occurs predominantly at the organic heterojunction. There may be, for example, a layer of acceptor material and a layer of donor material providing a substantially planar, discrete donor acceptor heterojunction; or a mixture of donor and acceptor materials providing an interpenetrating heterojunction; or a sandwich construction in which a layer of acceptor material and a layer of donor material have sandwiched between them a mixture of donor and acceptor materials.

Organic photovoltaic cells have limitations. The exciton diffusion length in organic semiconductors is short and typically less than 50 nm. In the context of a cell using a discrete heterojunction, this makes it necessary to use layer thicknesses that are insufficient to absorb all of the incident light, even after reflection from a back surface. In the context of an interpenetrating heterojunction cell, the layer thickness is limited not by the exciton diffusion length but by the low charge carrier mobility in a mixed layer of semiconductor materials. In addition, organic semiconductors typically have narrow absorption bandwidths, so that only part of the solar spectrum can be harvested by a given heterojunction material system.

In U.S. Pat. No. 6,657,378 there is proposed a photosensitive optoelectronic device comprising a plurality of organic semiconductor sub-cells arranged in a stack between electrodes, each sub-cell comprising donor material and acceptor material providing a heterojunction, and there being a recombination layer between adjacent sub-cells. In this US Patent, each sub-cell comprises a layer of acceptor material and a layer of donor material, so as to provide a discrete, planar heterojunction. A device of this type is frequently referred to as a “tandem cell” and may incorporate other layers that have no optical function but facilitate charge transport and/or extraction. In a tandem cell of this type, each sub-cell is too thin to harvest all of the incident light in the range of wavelengths over which the sub-cell is responsive, but because there is a plurality of sub-cells overall light absorption is increased.

It has been proposed that the sub-cells should have different properties in terms of frequency response, i.e. so that they have part of the light spectrum over which they are effective. This enables the tandem cell to absorb light in a greater range of wavelengths than if the sub-cells had the same frequency response properties. Such an arrangement is disclosed, for example, in U.S. Pat. No. 7,196,366.

In a typical tandem cell arrangement, one electrode is transparent allowing light into the cell from an external source such as the sun. The other electrode is opaque and reflective, thus reflecting light that has passed through the sub-cells back through the sub-cells. Where the sub-cells have different frequency responses, the sub-cell adjacent the transparent electrode absorbs the shortest wavelengths, and the sub-cell adjacent the opaque electrode absorbs the longest wavelengths. If there are intermediate sub-cells these absorb intermediate wavelengths. Adjacent sub-cells may be connected together in series using internal, thin transparent electrodes or semi-transparent electrodes such as metals or oxides. In some cases where a very thin layer of metal is deposited, for example of about 5 Å to about 20 Å, the layer may not be continuous but in the form of separated nanoparticles.

Viewed from one aspect, the present invention provides a photosensitive optoelectronic device comprising a plurality of organic semiconductor sub-cells arranged in a stack between electrodes, each sub-cell comprising donor material and acceptor material providing a heterojunction, and there being a recombination layer between adjacent sub-cells, wherein there are at least two groups of sub-cells, the sub-cells within a group being responsive over substantially the same part of the light spectrum, and the groups differing substantially from each other in respect of the parts of the light spectrum over which their respective sub-cells are responsive.

In preferred embodiments of the invention, within a group the absorption wavelength maxima of the sub-cells differ from each other by less than 10%. In preferred embodiments of the invention, the absorption wavelength maximum of each sub-cell within a group differs from the absorption wavelength maxima of the sub-cells within the or each other group by at least 10%.

As a whole, device in accordance with the invention provides the advantage of a tandem cell as disclosed in U.S. Pat. No. 7,196,366, by having an increased range of frequencies over which the device is operative. However, rather than the different ranges of frequencies being provided by individual sub-cells each harvesting a different part of the spectrum, in accordance with the present invention there is a plurality of groups of sub-cells, the sub-cells within a particular group being responsive over substantially the same part of the light spectrum. This means that for each particular band of wavelengths it is possible to increase the light harvesting efficiency of the device as a whole. Using a plurality of sub-cells for a particular frequency band enables the thickness of the organic layers to be kept thin whilst absorbing the maximum number of incident photons.

In some embodiments of the invention, preferably the sub-cells within a group are adjacent each other connected, and preferably connected together in series by means of a recombination layer, thus avoiding the need for an externally accessible transparent electrode between adjacent sub- cells. However, the groups of adjacent sub-cells may be connected together in series or parallel as desired. If the groups are connected together in series, this may be done by means of recombination layers, as used between adjacent sub-cells within the groups. If the groups are connected together in parallel, then between adjacent groups there should be a semi-transparent electrode which is addressable externally.

Within each sub-cell of a group, the combination of organic semiconductors will normally be the same, in terms of the donor and acceptor materials used. The ratios of the donor and acceptor materials may also be identical so that each sub-cell has the identical frequency response. However, within the frequency band of a particular group there may be some variations in the response characteristics of individual sub-cells. Preferably, within a group the absorption wavelength maxima of the sub-cells differ from each other by no more than 10% and preferably less than 10%. For example, the difference could be no more than about 9%; or no more than about 8%; or no more than about 7%; or no more than about 6%; or no more than about 5%.

By contrast, there will be a substantial difference in the frequency response of different groups and in preferred embodiments of the invention, the absorption wavelength maximum of each sub-cell within a group differs from the absorption wavelength maxima of the sub-cells within the or each other group by more than 10%. For example, the difference could be greater than about 20%; or greater than about 30%; or greater than about 40%; or greater than about 50%.

Within a particular group, the thickness of the sub-cells may be varied so as to optimise efficiency.

The front of the photovoltaic device, to which light is directed, may comprise an inert transparent substrate, to which a transparent electrode is attached. For example, the substrate itself may be in the form of a transparent glass or polyethylene terephthalate (PET) coated with a thin film of the transparent conducting oxide indium tin oxide (ITO). The back of the device may be provided with an opaque, reflective electrode of a metal such as silver, aluminium or calcium or any combination thereof. Transparent or semi-transparent electrodes may be thin metal layers of, for example, silver, aluminium or titanium, or may be layers of transparent conducting oxides such as indium tin oxide (ITO), zinc indium tin oxide or gallium indium tin oxide, or any other suitable materials including conductive polymers such as polyanaline.

In some embodiments the electrode at or adjacent the front of the device is an anode.

In some embodiments, an exciton blocking layer is provided between adjacent sub-cells within a group, and in the case of bi-layer sub-cells the exciton blocking layer can be situated between the acceptor organic semiconductor layer of the sub-cell and the recombination layer between that sub-cell and another sub-cell in the group.

In some embodiments, an exciton blocking layer is provided between each group, the exciton blocking layer being situated between the acceptor organic semiconductor layer of a sub-cell of one group, and a recombination layer or electrode between that group and another group.

An exciton blocking layer may be provided between a cathode and an adjacent sub-cell. The terms anode and cathode used in this specification apply to the photosensitive device being subjected to light and providing an electrical potential across a resistive load, and the cathode is the electrode to which electrons move within the device.

Exciton blocking layers are described, for example, in U.S. Pat. Nos. 6,097,147 and 6,657,378. Suitable materials for such a layer could be bathocuproine (BCP), which is 2,9-dimethyl-4,7-diphenyl-1,10-phenanthroline, or Alq₂OPH which is bis (2-methyl-8-hydroxyquinolinoato)-aluminium(III) phenolate. In some preferred embodiments of the present invention, BCP is used as the exciton blocking layer.

There may be an interlayer between an anode and an adjacent sub-cell, to assist the attraction of holes. Such an interlayer could be a very thin layer of an oxide such as molybdenum oxide, MoO₃ or tungsten oxide, WO₃. It has been found that the short-circuit current of photovoltaic cells with an MoO₃ or WO₃ interlayer can be enhanced, with an enhancement in power conversion efficiency. A very thin MoO₃ or WO₃ layer (typically about 5 nm) at the interface between the transparent conducting electrode and an organic donor layer such as chloroaluminium phthalocyanine can greatly assist the extraction of holes, which is highly beneficial for raising the performance of the device (current, voltage and efficiency). However, it depends critically on the energy level alignment at the electrode-organic interface, i.e. it depends on what type of organic donor layer is used. For example, it has been found that chloro-aluminium phthalocyanine devices can work much better if provided with such an interlayer. Other research has suggested that an interlayer also improves the performance of devices using tin (II) phthalocyanine (SnPc) as the donor layer. Other oxides may also be suitable for the interlayer.

In the sub-cells, the acceptor material may be, for example, perylenes, napthalenes, fullerenes, nanotubules or siloles. In some preferred embodiments of the present invention, the acceptor material is Buckminster fullerene (C₆₀). The organic donor material may be, for example, a phthalocyanine, porphyrin or acene or a derivative thereof or a metal complex thereof such as copper pthalocyanine. One preferred donor material in embodiments of the present invention is chloro-aluminium phthalocyanine, and another is sub-phthalocyanine. In the field of organic heterojunction solar cells, a number of substances have been proposed for donor and acceptor layers and are known to those skilled in the art. The present invention is not limited to the use of particular donor and acceptor materials.

The groups may be connected in series or in parallel. In a series arrangement, there will be generally be an anode at one end of the stack of groups and a cathode at the other end of the stack of groups. In each group, electrons will move in the same direction. In a parallel arrangement with two groups, there will be electrodes at either end of the stack which are connected together, and a common electrode between the two groups of sub-cells. If there are more than two groups connected in a parallel arrangement, there will be a common electrode between groups. It would be possible to have a series/parallel arrangement, in which a number of groups are arranged in series, and are then connected in parallel to another group or to a number of series connected groups.

In the preferred embodiments, in any given group there is a plurality of adjacent sub-cells, all having substantially the same frequency response. In an alternative arrangement it would be possible to distribute cells within a given group throughout the stack, rather than have them adjacent. For example if there are two groups, the sub-cells from the different groups could alternate within the stack. This could increase the complexity of manufacture but might assist in achieving more a level frequency response for the device as a whole.

Within a particular group, in embodiments of the invention it is envisaged that there may be between two and five sub-cells, and preferably two or three sub-cells.

Within the device as a whole there may be between two and five groups of sub-cells, and preferably two or three groups.

The provision of a number of a number of groups of sub-cells, with the sub-cells connected together in series and the groups connected together in parallel is a novel arrangement and thus viewed from another aspect, the invention provides a photosensitive optoelectronic device comprising a plurality of organic semiconductor sub-cells arranged in a stack between electrodes, each sub-cell comprising donor material and acceptor material providing a heterojunction, and there being a recombination layer between adjacent sub-cells, wherein there is a plurality of groups of adjacent sub-cells, the sub-cells within a group being connected together in series, and the cell groups being connected together in parallel.

In such an arrangement the groups may all be connected together in parallel, or a number of groups may be connected together in series and then connected in parallel to another group, or to a series of connected groups.

The various features discussed in connection with the first aspect of the invention are equally applicable to this aspect of the invention.

The invention also extends to photovoltaic modules and panels incorporating devices as described above, and to solar powered electrical generating systems incorporating one or more such modules and/or panels.

Some embodiments of the invention will now be described by way of example and with reference to the accompanying drawings, in which:

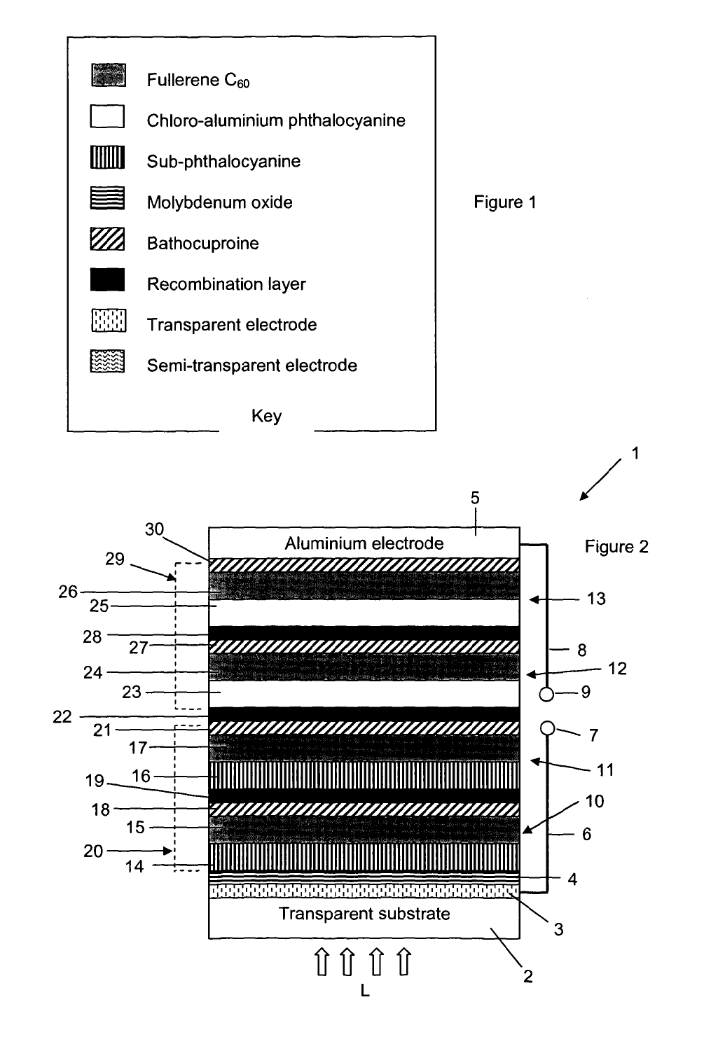

FIG. 1 is a key to layers used in embodiments of the invention;

FIG. 2 is a diagrammatic view of a first embodiment of the invention;

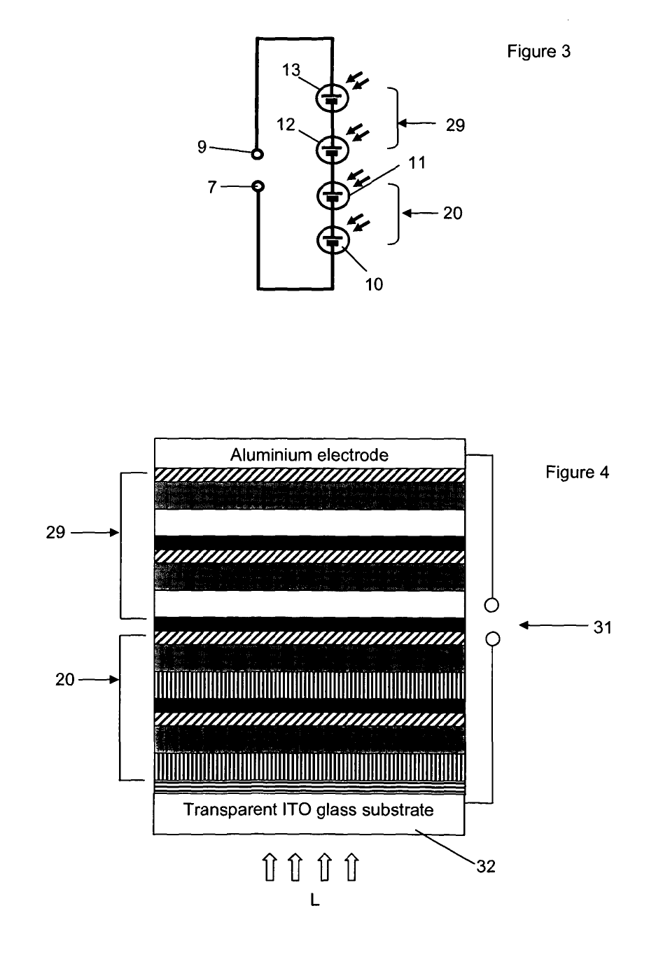

FIG. 3 is a circuit diagram of the first embodiment;

FIG. 4 is a diagrammatic view of .a modification of the first embodiment of the invention;

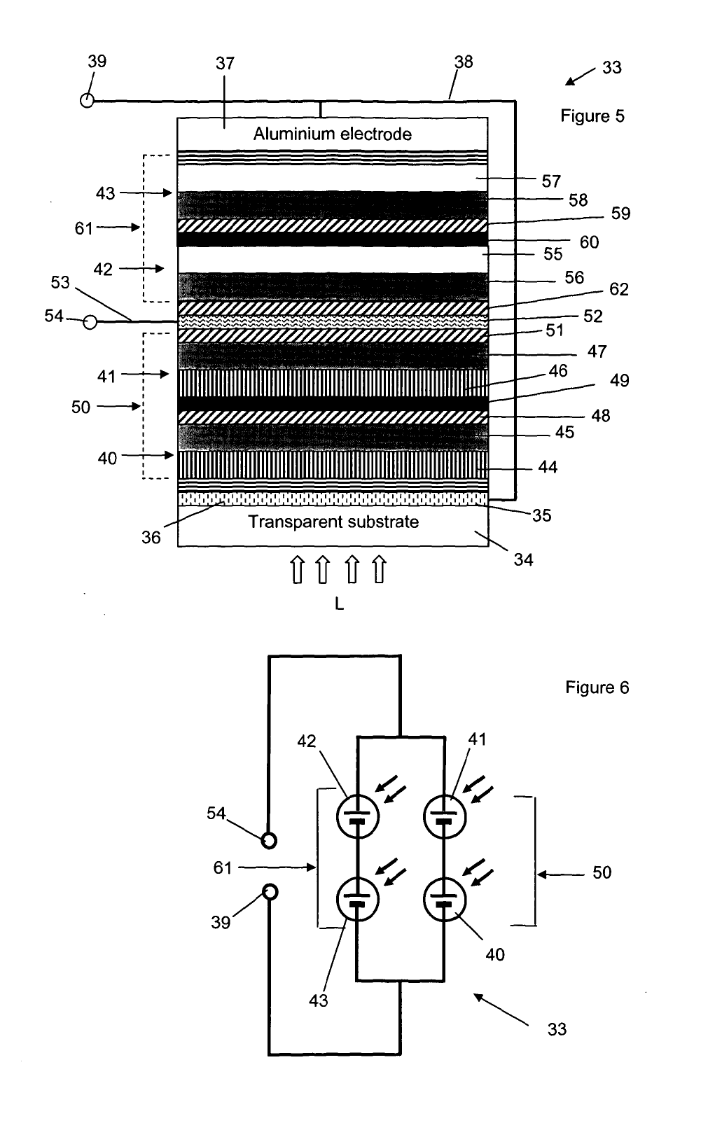

FIG. 5 is a diagrammatic view of a second embodiment of the invention; and

FIG. 6 is a circuit diagram of the second embodiment.

FIG. 1 shows a key to the layers shown in FIGS. 2, 4 and 5. Fullerene C₆₀ is used as an acceptor layer. Chloro-aluminium phthalocyanine and sub-phthalocyanine are used as donor layers. Molybdenum oxide is used as an interlayer between an anode and the donor layer of a sub-cell. Bathocuproine (BCP) is used as an exciton blocking layer. A recombination layer may be in the form of a semi-transparent thin metal layer of silver, aluminium or titanium, or may be a transparent layer of a conducting oxide such as indium tin oxide (ITO), zinc indium tin oxide or gallium indium tin oxide, or may provide discrete recombination centres. A transparent electrode may be a transparent layer of a conducting oxide such as indium tin oxide (ITO), zinc indium tin oxide or gallium indium tin oxide. A semi-transparent electrode may be a thin metal layer of silver, aluminium or titanium.

FIG. 1 shows an organic semiconductor photovoltaic device 1 in accordance with the invention. The device comprises a transparent substrate 2 at one end arranged to receive light L, on which is a semitransparent electrode 3 serving as the anode in this arrangement. On top of this is a thin interlayer 4 of molybdenum oxide, about 5 nm thick. At the other end of the device is a reflective aluminium electrode 5 which serves as the cathode in this device. Conductor 6 is connected to the anode 3 and terminates in a connector 7, and conductor 8 is connected to the cathode 5 and terminates in a connector 9. In use a load will be placed across the connectors 7 and 9.

Between the anode 3 and cathode 5 is a stack of four organic semiconductor sub-cells 10, 11, 12 and 13. Each sub-cell includes a donor and acceptor layer. Sub cell 10 has a donor layer 14 of sub-phthalocyanine and an acceptor layer 15 of fullerene C₆₀. Adjacent cell 11 also has a donor layer 16 of sub-phthalocyanine and an acceptor layer 17 of fullerene C₆₀. Between sub-cells 10 and 11 is a BCP exciton blocking layer 18 and a recombination layer 19. Sub-cells 10 and 11 have substantially the same response characteristics, in this embodiment in the green and yellow part of the spectrum, and constitute a first group 20.

Between sub-cell 11 and sub-cell 12 there is a BCP exciton blocking layer 21 and a recombination layer 22.

Sub cell 12 has a donor layer 23 of chloro-aluminium phthalocyanine and an acceptor layer 24 of fullerene C₆₀. Adjacent cell 13 also has a donor layer 25 of chloro-aluminium phthalocyanine and an acceptor layer 26 of fullerene C₆₀. Between sub-cells 12 and 13 is a BCP exciton blocking layer 27 and a recombination layer 28. Sub-cells 12 and 13 have substantially the same response characteristics, in this embodiment in the red part of the spectrum, and constitute a second group 29. Between acceptor layer 26 and the aluminium electrode 5 is an exciton blocking layer 30 of BCP.

In this arrangement the sub-cells 10, 11, 12 and 13 are arranged in series between the anode 3 and cathode 5, as shown in FIG. 3.

FIG. 4 shows a modified device 31 in accordance with this embodiment, in which the transparent electrode 3 has been removed, and the transparent substrate 2 has been replaced by a transparent ITO substrate 32 which acts as the anode.

FIG. 5 shows an alternative embodiment of an organic semiconductor photovoltaic device 33. The device 33 comprises a transparent substrate 34 at one end arranged to receive light L, on which is a semitransparent electrode 35 serving as an anode in this arrangement. On top of this is an interlayer 36 of molybdenum oxide. At the other end of the device is a reflective aluminium electrode 37 which also serves as an anode in this device and is connected by a conductor 38 to electrode 35. Conductor 38 terminates in a connector 39.

Between the anodes 35 and 37 is a stack of four organic semiconductor sub-cells 40, 41, 42 and 43. Each sub-cell includes a donor and acceptor layer. Sub cell 40 has a donor layer 44 of sub-phthalocyanine and an acceptor layer 45 of fullerene C₆₀. Adjacent cell 41 also has a donor layer 46 of sub-phthalocyanine and an acceptor layer 47 of fullerene C₆₀. Between sub-cells 40 and 41 is a BCP exciton blocking layer 48 and a recombination layer 49. Sub-cells 40 and 41 have substantially the same response characteristics, in this embodiment in the green and yellow part of the spectrum, and constitute a first group 50.

Between sub-cell 41 and sub-cell 42 there is a BCP exciton blocking layer 51 and a semitransparent electrode 52, which in this arrangement acts at the cathode. A conductor 53 leads from the electrode 52 and terminates in a connector 54. In use a load will be placed across the connectors 39 and 54.

Sub cells 42 and 43 have their organic semiconductor layers reversed as compared to the layers in sub-cells 12 and 13, as the aluminium electrode 37 is now an anode and the cathode is the electrode 52. In this context the molybdenum oxide layer adjacent to the aluminium electrode could, for example, be replaced with a thin layer of tungsten trioxide (WO₃) or vanadium oxide (V₂O₅).

Sub-cell 42 has a donor layer 55 of chloro-aluminium phthalocyanine and an acceptor layer 56 of fullerene C₆₀. Adjacent sub-cell 43 also has a donor layer 57 of chloro-aluminium phthalocyanine and an acceptor layer 58 of fullerene C₆₀. Between sub-cells 42 and 43 is a BCP exciton blocking layer 59 and a recombination layer 60. Sub-cells 42 and 43 have substantially the same response characteristics, in this embodiment in the red part of the spectrum, and constitute a second group 61. Between acceptor layer 56 and the electrode 52 is an exciton blocking layer 62 of BCP.

In this arrangement the sub-cells 40 and 41 of first group 50 are arranged in series, and the sub-cells 42 and 43 of second group 61 are arranged in series. However, the first and second groups are arranged in parallel as shown in FIG. 6.

In the embodiments described above, each sub-cell has a thickness which is less than the optical absorption length. An individual sub-cell has a thickness which is too small for the sub-cell to absorb all of the incident light over the range of wavelengths for which the sub-cell is responsive.

There are thus provided organic photovoltaic devices which can operate with improved efficiency across a broad spectrum.

It will be appreciated that the embodiments described are by way of example and for the purposes of illustrating the principal features of the invention. Many modifications may be made to the embodiments without departing from the scope of the invention.

1. A photosensitive optoelectronic device comprising a plurality of organic semiconductor sub-cells arranged in a stack between electrodes, each sub-cell comprising donor material and acceptor material providing a heterojunction, and there being a recombination layer between adjacent sub-cells, wherein there are at least two groups of sub-cells, the sub-cells within a group being responsive over substantially the same part of the light spectrum, and the groups differing substantially from each other in respect of the parts of the light spectrum over which their respective sub-cells are responsive.

2. A device as claimed in claim 1, wherein within a group the absorption wavelength maxima of the sub-cells differ from each other by less than 10%.

3. A device as claimed in claim 2, wherein the absorption wavelength maximum of each sub-cell within a group differs from the absorption wavelength maxima of the sub-cells within the or each other group by at least 10%.

4. A device as claimed in claim 1, wherein the sub-cells within a group are stacked adjacent each other.

5. A device as claimed in claim 4, wherein between a sub-cell and an adjacent sub-cell in the same group, there is provided an exciton blocking layer in addition to a recombination layer.

6. A device as claimed in claim 4, wherein at least some groups are connected together in series.

7. A device as claimed in claim 6, wherein between adjacent series connected groups there is a recombination layer.

8. A device as claimed in claim 7, wherein between one of the series connected groups and the recombination layer between that group and an adjacent series connected group, there is provided an exciton blocking layer.

9. A device as claimed in claim 1, wherein at least some groups are connected together in parallel.

10. A device as claimed in claim 9, wherein between adjacent parallel connected groups there is an externally addressable electrode.

11. A device as claimed in claim 10, wherein between one of the parallel connected groups and the externally addressable electrode between that group and an adjacent parallel connected group, there is provided an exciton blocking layer

12. A device as claimed in claim 1, wherein at least some of the sub-cells comprise discrete layers of donor and acceptor materials.

13. A device as claimed in claim 12, wherein at least some of the sub-cells comprise discrete layers of donor and acceptor materials, between which is sandwiched a layer which is a mixture of donor and acceptor materials.

14. A device as claimed in claim 1, wherein each sub-cell has a thickness which is less than the optical absorption length.

15. A device as claimed in claim 1, wherein within a group the sub-cells have the same donor material and the same acceptor material.

16. A device as claimed in claim 1, wherein between an anode of the device and an adjacent sub-cell, there is provided an interlayer of molybdenum oxide.

17. A device as claimed in claim 1, wherein the acceptor material of sub-cells is selected from perylenes, napthalenes, fullerenes, nanotubules or siloles.

18. A device as claimed in claim 17, wherein the acceptor material in at least one sub-cell is fullerene C₆₀.

19. A device as claimed in claim 1, wherein the donor material of sub-cells is selected from a phthalocyanine, porphyrin or acene or a derivative thereof or a metal complex thereof.

20. A device as claimed in claim 19, wherein the donor material of at least one sub-cell is chloro-aluminium phthalocyanine.

21. A device as claimed in claim 19, wherein the donor material of at least one sub-cell is sub-phthalocyanine.

22. A photovoltaic module incorporating a plurality of devices as claimed in claim 1.

23. (canceled)

24. A photosensitive optoelectronic device comprising a plurality of organic semiconductor sub-cells arranged in a stack between electrodes, each sub-cell comprising donor material and acceptor material providing a heterojunction, and there being a recombination layer between adjacent sub-cells, wherein there is a plurality of groups of adjacent sub-cells, the sub-cells within a group being connected together in series, and the cell groups being connected together in parallel.

25. A photovoltaic module incorporating a plurality of devices as claimed in claim 24.

26. (canceled)
